(19) United States
(12) Patent Application Publication
(10) Pub. No.: US 2012/0112772 A1
(43) Pub. Date: May 10, 2012

(54) CIRCUIT FOR DETECTING CAPACITANCE ATTENUATION OF RECTIFICATION/FILTER CAPACITOR AND METHOD THEREOF

(76) Inventor: Jui-Kun HUANG, Kaohsiung City (TW)

(21) Appl. No.: 12/941,649

(22) Filed: Nov. 8, 2010

(51) Int. Cl. G01R 27/26

(52) U.S. Cl. 324/659

(57) ABSTRACT

The present invention discloses a circuit for detecting capacitance attenuation of a rectification/filter capacitor and a method thereof. A rectification circuit provides a capacitor with a rectified ripple voltage having a maximum lower than output voltage of a back-up power supply device. An isolation device isolates the rectified ripple voltage and let the back-up power supply device supply power to other power supply devices. The detection switch of an detection circuit is turned on to electrically connect the capacitor with a resistor, whereby the resistor conducts the rectified ripple voltage to charge and discharge the capacitor to obtain a peak-to-valley ratio and a discharging time. The capacitance is worked out from the peak-to-valley ratio, discharging time and resistance of the resistor. The deterioration extent of the capacitor is obtained from the variation of the capacitance. Therefore, the UPS system would not be shut off during detecting the capacitor.

### FIELD OF THE INVENTION

The present invention relates to a circuit for detecting capacitance attenuation of a rectification/filter capacitor and a method thereof, particularly to a circuit for detecting capacitance by a ripple voltage of a rectification/filter capacitor and a method thereof in the operation of a UPS (Uninterrupted Power Supply) system.

### BACKGROUND OF THE INVENTION

A deteriorated capacitor has a degraded filtering effect, magnifies the ripple voltage at the DC side and thus damages the energy storage device. The energy storage device is an important and precious apparatus in a UPS system, and protecting the capacitor is a top priority in protecting the energy storage device. Temperature is the primary factor causing the deterioration of a capacitor. After long-term usage, high temperature dries up the electrolyte of the capacitor and attenuates the capacitance of the capacitor. However, current electronic devices and precision apparatuses require higher and higher reliability of the UPS system. In the conventional technology, before the technician examines the deterioration of the DC capacitor in the operation of a UPS system, power supply has to be switched from the UPS system to other power sources, and the UPS system has to be shut off. To solve the abovementioned problem, the present invention proposes a circuit for detecting capacitance attenuation of a rectification/filter capacitor and a method thereof, wherein the capacitors of an operating UPS system can be inspected without interfering with the power supply devices at the output of the UPS system.

### SUMMARY OF THE INVENTION

The present invention proposes a circuit for detecting capacitance attenuation of a rectification/filter capacitor and a method thereof to overcome the conventional problem that a UPS system must be shut off before the technician examines the capacitance of the capacitor of the UPS system, whereby the capacitor of an operating UPS system can be inspected without interfering with the power supply devices at the output of the UPS system.

To achieve the abovementioned objective, the present invention proposes a circuit for detecting capacitance attenuation of a rectification/filter capacitor, wherein an capacitor has one side connected with a detection circuit, and the detection circuit includes a detection switch and a resistor connected in series, and an isolation device is interposed between and connected in series with an back-up power supply device and the output of the capacitor and the detection circuit to prevent the back-up power supply device from discharging electricity to the capacitor and the detection circuit. The isolation device includes a plurality of diodes connected in parallel or a plurality of unidirectional thyristors connected in parallel to prevent disconnection and malfunction when one of the diodes or unidirectional thyristors fails. A rectified ripple voltage is supplied to the capacitor. In the event that the rectified ripple voltage has a maximum lower than the voltage of the back-up power supply device, the isolation device isolates the rectified ripple voltage and the output power is supplied by the back-up power supply device. The capacitor receives the rectified ripple voltage from the detection circuit, and the resistor performs charging and discharging to work out the capacitance.

The present invention improves the conventional method for detecting the deterioration of capacitors. In the present invention, a rectified ripple voltage is regulated by a rectifier and used to detect the capacitance of the capacitor via a resistor of the detection circuit. During detection, the output power is supplied by a back-up power supply device. Therefore, the present invention can detect capacitors without shutting off the UPS system and supplying power by other bypass power supply devices.

The circuit and method for detecting capacitance attenuation of a rectification/filter capacitor of the present invention can regulate the rectified ripple voltage by the rectifier and detect the capacitance of a capacitor via the resistor of the detection circuit without interrupting the operation of the UPS system. During detection, the output power is supplied by a back-up power supply device. When the back-up power supply device operates abnormally, an isolation device is turned on to let the rectified ripple voltage resume supplying power. Therefore, power supply would not be interrupted during detecting the capacitor of the preset invention.

The circuit and method for detecting capacitance attenuation of a rectification/filter capacitor of the present invention have the following advantages:

1. The present invention can detect capacitance of the capacitor of a UPS system without interrupting the operation of the UPS system and interfering with other power supply devices.

2. The isolation device of the present invention includes a plurality of diodes connected in parallel or a plurality of unidirectional thyristors connected in parallel. Therefore, a single diode or unidirectional thyristor fails would not interrupt power supply in the present invention.

### BRIEF DESCRIPTION OF THE DRAWINGS

FIG. 1 is a diagram showing a circuit for detecting capacitance attenuation of a rectification/filter capacitor according to the present invention;

FIG. 2 is a diagram showing the waveform of a single-phase full-wave rectified ripple voltage according to the present invention;

FIG. 3 is a diagram showing the circuit consists of a plurality of capacitors according to the present invention;

FIG. 4 is a diagram showing a waveform-rectification circuit according to the present invention;

FIG. 5 is a diagram showing another waveform-rectification circuit according to the present invention;

FIG. 6 is a diagram showing the waveform of a single-phase half-wave rectified ripple voltage according to the present invention;

FIG. 7 is a diagram showing a rectification circuit according to one embodiment of the present invention; and

FIG. 8 is a diagram showing another rectification circuit according to one embodiment of the present invention.

### DETAILED DESCRIPTION OF THE PREFERRED EMBODIMENTS

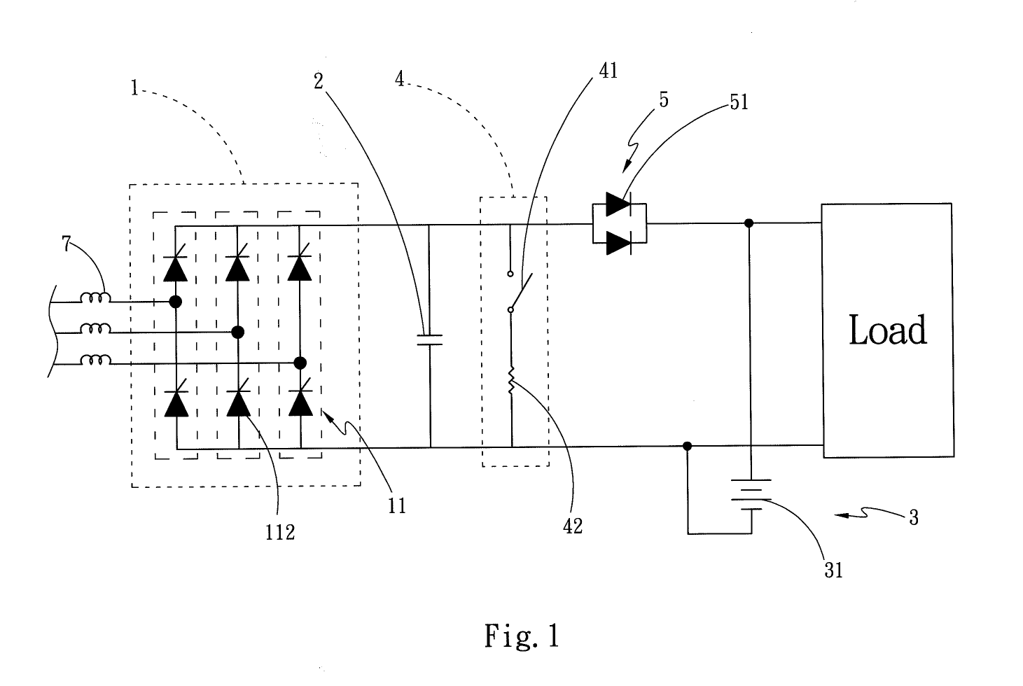

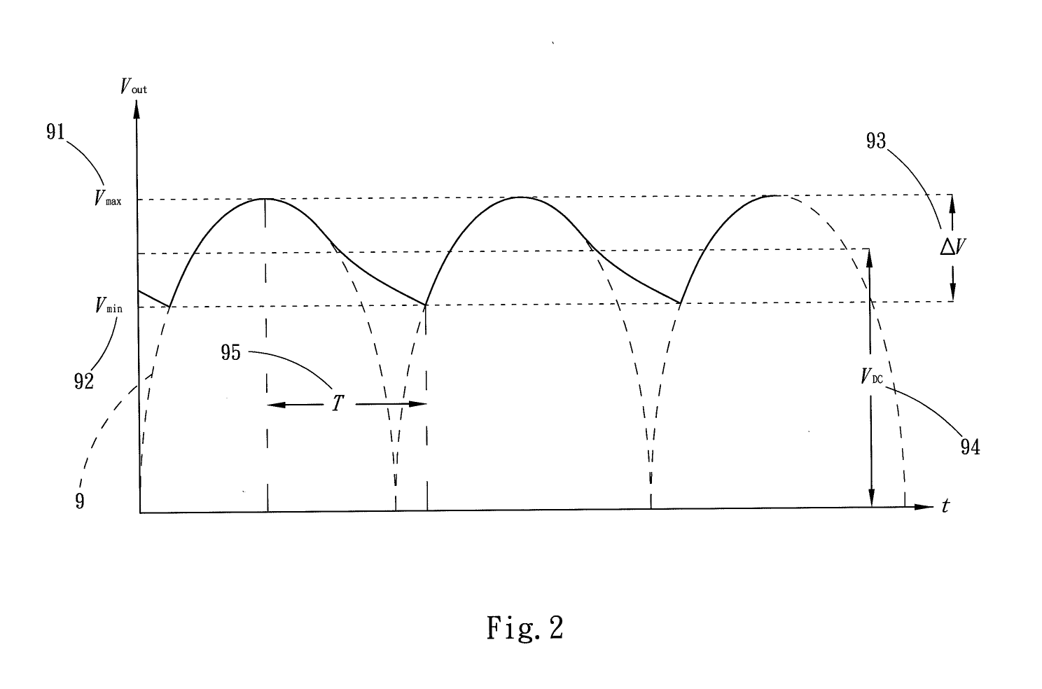

Refer to FIG. 1 and FIG. 2. The circuit for detecting capacitance attenuation of a rectification/filter capacitor comprises a rectification circuit 1, at least one capacitor 2, a back-up power supply device 3, a detection circuit 4 and an isolation device 5.

The rectification circuit 1 includes a plurality of phase-controlled circuits 11 connected in parallel. Each phase-controlled circuit 11 is connected with a filter inductor 7 filtering out the noise of the external power. Each phase-controlled circuit 11 includes a plurality of thyristors 112 and provides a rectified ripple voltage 9 for the capacitor 2.

The capacitor 2 is connected with the rectification circuit 1 and receives the rectified ripple voltage 9 from the rectification circuit 1.

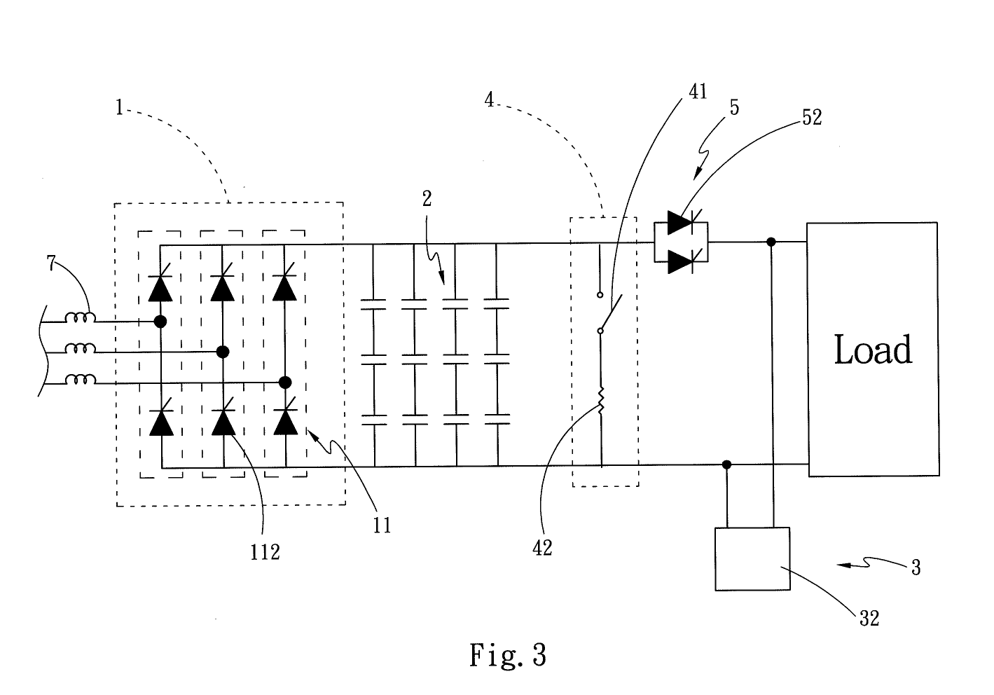

The back-up power supply device 3 is connected with the capacitor 2 and supplies power for the system when the capacitor 2 is detected. The back-up power supply device 3 may be an energy storage element 31 (such as a battery) or a DC power supply 32 (as shown in FIG. 3).

The detection circuit 4 is connected with one side of the capacitor 2 and includes at least one detection switch 41 and at least one resistor 42 connected in series.

The isolation device 5 is arranged between the back-up power supply device 3 and the output of the capacitor 2 and detection circuit 4 that are connected in series. The isolation device 5 is used to prevent the back-up power supply device 3 from discharging electricity to the capacitor 2 and the detection circuit 4. The isolation device 5 includes a plurality of diodes 51 connected in parallel or a plurality of unidirectional thyristors 52 connected in parallel (as shown in FIG. 3). The parallel connected diodes 51 or unidirectional thyristors 52 are used to guarantee that the back-up power supply device 3 can keep on supplying power when one of the diodes 51 or unidirectional thyristors 52 malfunctions. The unidirectional thyristor 52 may be a silicon controlled rectifier.

The objective of the present invention is to detect the capacitance C of a UPS system without interrupting the operation thereof. Refer to FIG. 1 and FIG. 2 again. During detection, one of the phase-controlled circuits 11 is turned off and other thyristors 112 are all turned on and their firing angle are zero degree, whereby the rectified ripple voltage 9 supplied to the capacitor 2 is a single-phase full-wave rectified voltage. The maximum of the rectified ripple voltage 9 is lower than the output voltage of the back-up power supply device 3. Thus, the isolation device 5 isolates the low rectified ripple voltage 9, and the output of the UPS system is supplied by the back-up power supply device 3. After the back-up power supply device 3 is isolated, the detection switch 41 is ON to electrically connect the resistor 42 with the capacitor 2. Thus, the resistor 42 of the detection circuit 4 conducts the rectified ripple voltage 9 to persistently charge and discharge electricity to the capacitor 2 for detecting the maximum voltage Vₘₐₓ 91 and the minimum voltage Vₘᵢₙ 92. As shown in FIG. 2, the voltage has a maximum value Vₘₐₓ 91 at the instant when the capacitor 2 is charged to saturation and then discharges; the voltage has a minimum value Vₘᵢₙ 92 at the instant when the capacitor 2 that originally discharges is charged. The peak-to-valley ratio ΔV 93 and the average DC voltage V_{DC} 94 can be derived from the maximum voltage Vₘₐₓ 91 and the minimum voltage Vₘᵢₙ 92, wherein ΔV=

$${V}_{max} - {V}_{min} , and {V}_{DC} = \frac{{V}_{max} + {V}_{min}}{2} .$$

The interval between the maximum voltage Vₘₐₓ 91 and the minimum voltage Vₘᵢₙ 92 is the discharging time T 95. Thus,

$${I}_{DC} = \frac{{V}_{DC}}{R} ,$$

wherein R is the resistance of the resistor 42.

$$As Q = Δ V \times C = {I}_{DC} \times T , C = \frac{T}{Δ V} \times {I}_{D C} ,$$

wherein Q is the discharge of the capacitor 2. Therefore, the capacitance C of the capacitor 2 can be obtained via detecting Vₘₐₓ 91, Vₘᵢₙ 92 and T 95. Then, the deterioration extent of the capacitor 2 can be obtained from the capacitance C.

Refer to FIG. 1 and FIG. 2 again. Once the output voltage of the back-up power supply device 3 is lower the rectified ripple voltage 9 in the detection process, the isolation device 5 is turned on and the rectified ripple voltage 9 takes over to supply power to the system. Therefore, the UPS system would not suffer from power interruption while detecting the capacitor.

Refer to FIG. 3. There are a plurality of capacitors 2 connected in series or in parallel. The detected capacitance C is the total capacitance of all the capacitors 2.

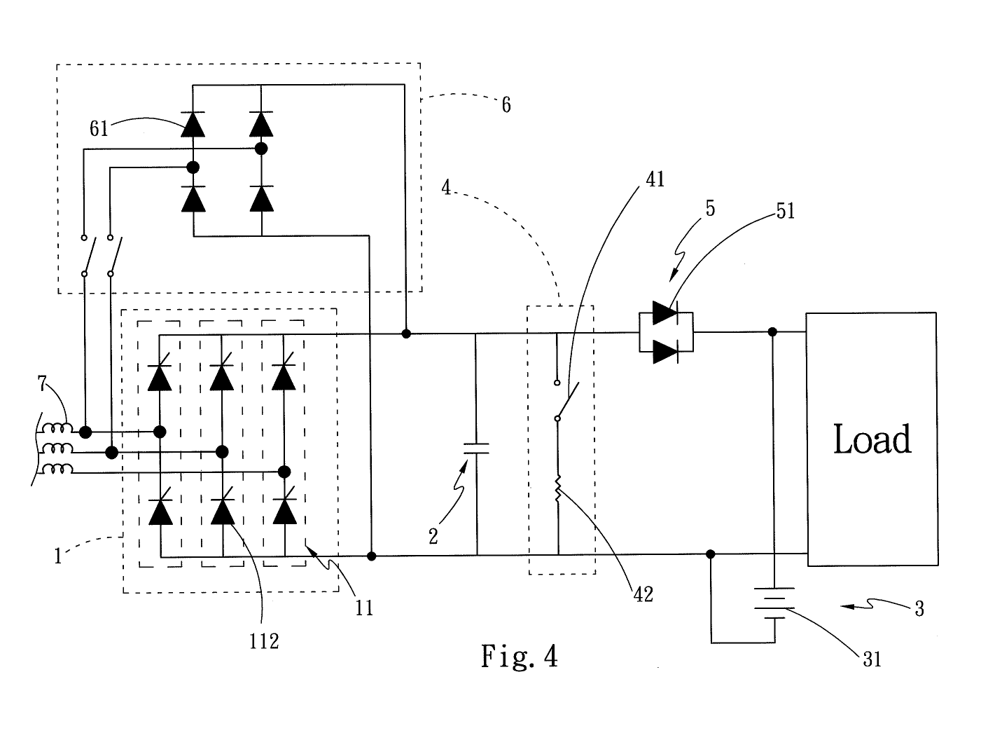

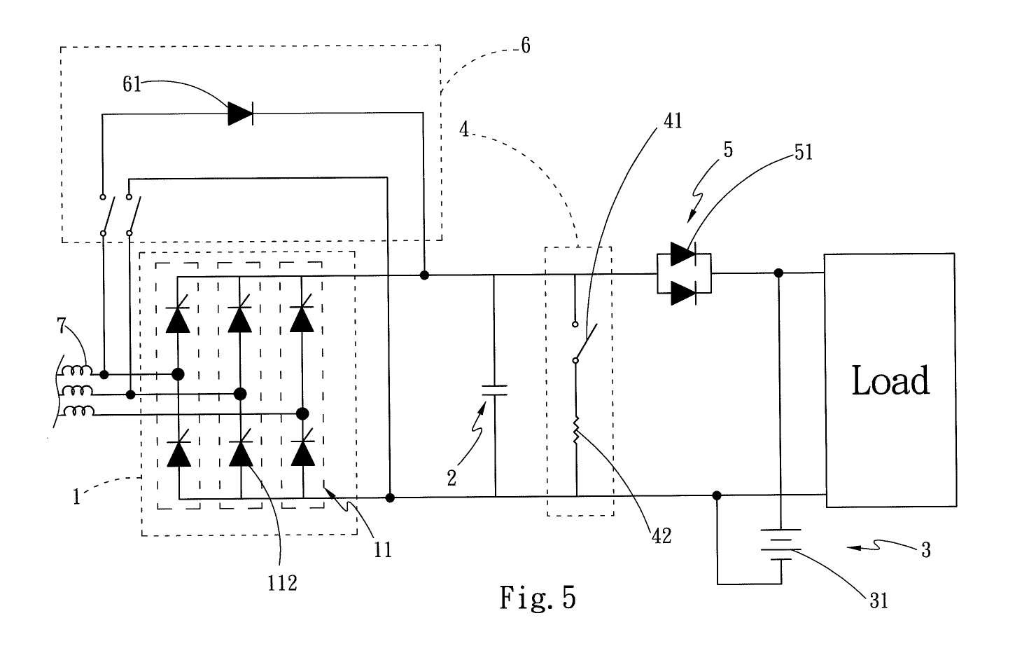

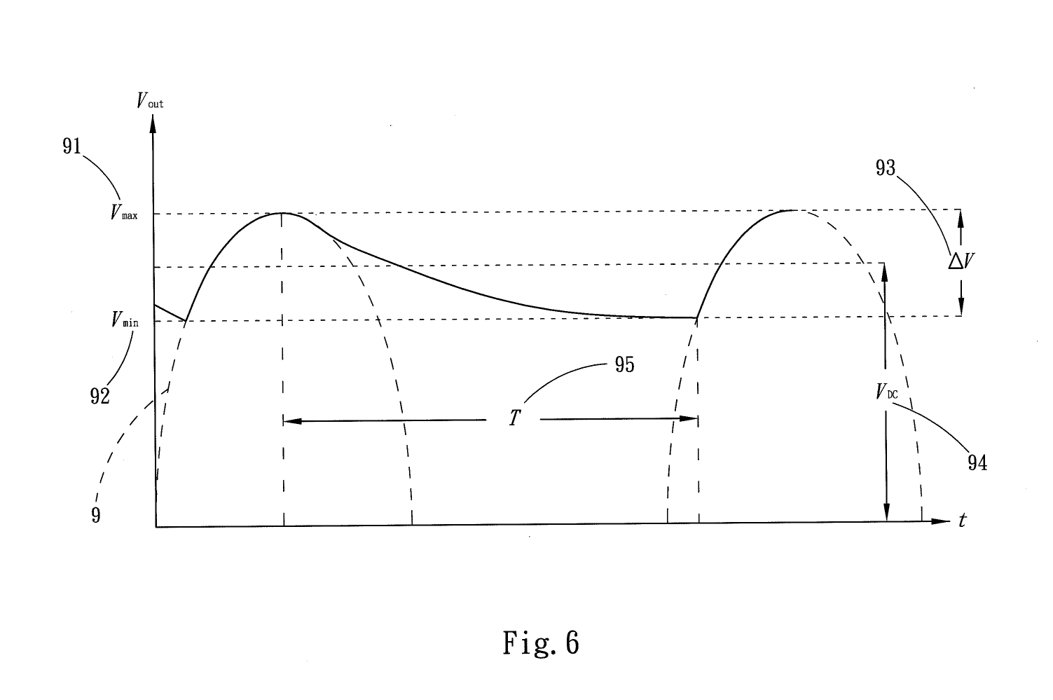

Refer to FIG. 2 and FIG. 4. In one embodiment, the rectified ripple voltage 9 is supplied by a waveform-rectification circuit 6. The waveform-rectification circuit 6 includes a plurality of diodes 61 connected in series and in parallel and powered by an external power source. The waveform-rectification circuit 6 is connected with the capacitor 2. In detecting the capacitor 2, the rectification circuit 1 is turned off and the waveform-rectification circuit 6 is turned on to supply the rectified ripple voltage 9 to the capacitor 2. The rectified ripple voltage 9 supplied by the waveform-rectification circuit 6 and the rectification circuit 1 is a single-phase full-wave rectified voltage. Refer to FIG. 5. In one embodiment, the rectified ripple voltage 9 is a single-phase half-wave voltage. In such a case, the waveform-rectification circuit 6 has a single diode 61 connected with an external power source and the capacitor 2 in series, whereby to supply a single-phase half-wave voltage, as shown in FIG. 6.

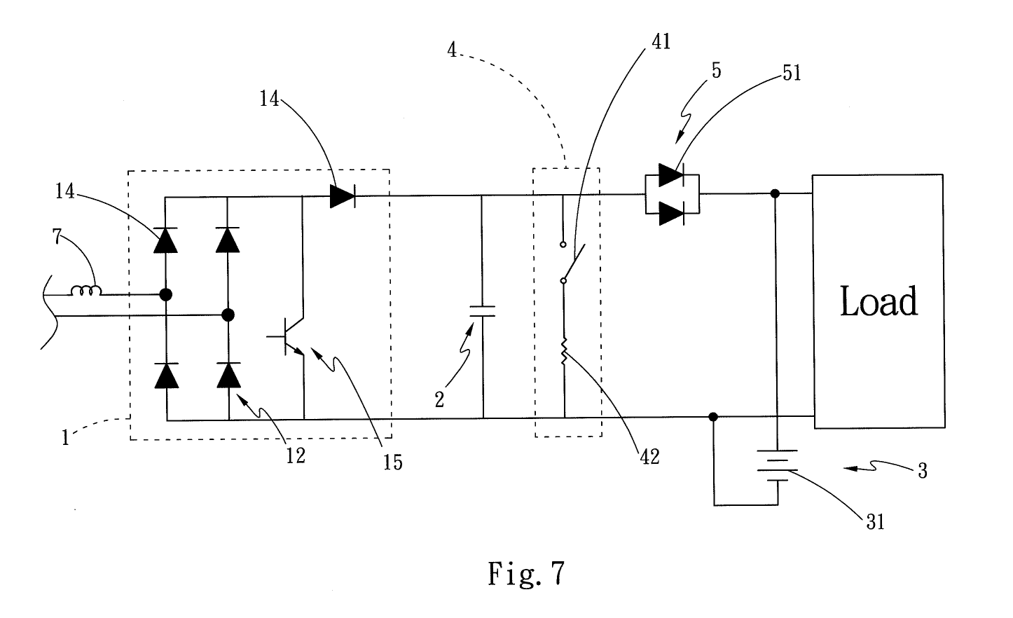

Refer to FIG. 2 and FIG. 7. In one embodiment, the rectification circuit 1 is a single-phase high power factor rectifying-charging circuit, which is applied to a small-capacity power supply system. The single-phase high power factor rectifying-charging circuit includes two control circuits 12 and a transistor switch 15 connected sequentially in parallel, and the output terminal thereof is connected with a diode 14 in series. Each control circuit 12 includes two diodes 14 connected in series. One of the control circuits 12 is connected with a filter inductor 7 to filter out the noise of the external power. When the transistor switch 15 is turned off, the rectification circuit 1 supplies a single-phase full-wave rectified ripple voltage 9 to the capacitor 2 and the detection circuit 4 to detect the capacitance C.

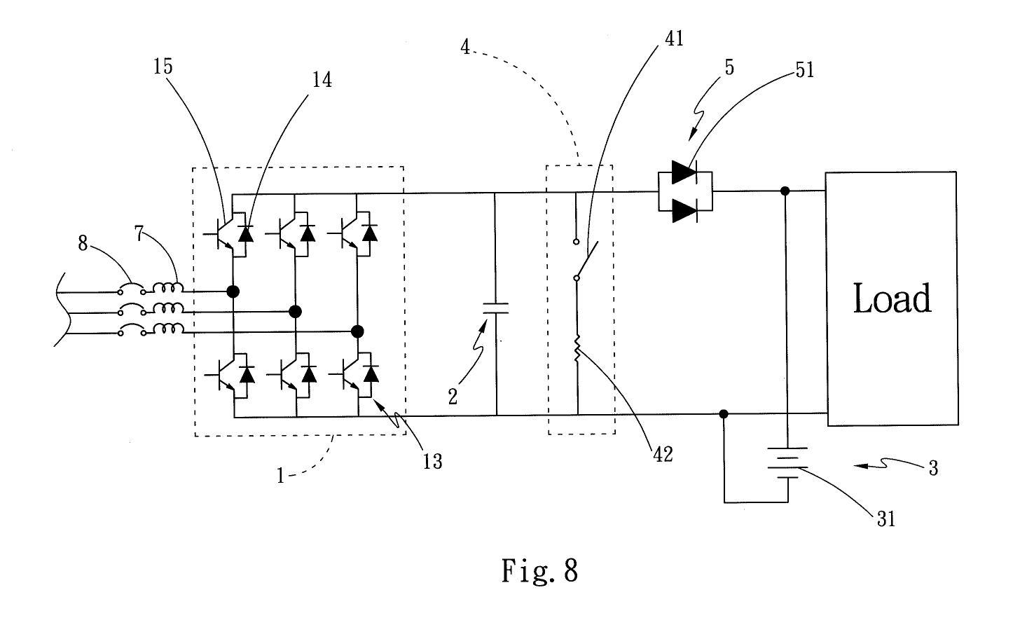

Refer to FIG. 2 and FIG. 8. In one embodiment, the rectification circuit 1 is a three-phase high power factor rectifying-charging circuit, which is applied to a large-capacity power supply system. The three-phase high power factor rectifying-charging circuit includes a plurality of switch circuits 13 connected in parallel. Each switch circuit 13 includes two diodes 14 connected in series, and each diode 14 is connected with a transistor switch 15 in parallel. Each switch circuit 13 is connected with a filter inductor 7 and a switch 8 to receive the external power. When one of the switches 8 and all the transistor switches 15 in the rectification circuit 1 are turned off, the rectification circuit 1 supplies a single-phase full-wave rectified ripple voltage 9 to the capacitor 2 and the detection circuit 4.

What is claimed is:

1. A circuit for detecting capacitance attenuation of a rectification/filter capacitor, comprising:
at least one capacitor receiving a rectified ripple voltage;
a back-up power supply device connected with the capacitor and supplying power in detecting the capacitor;
a detection circuit connected with one side of the capacitor and including at least one detection switch and at least one resistor connected in series; and
an isolation device arranged between and connected in series with the back-up power supply device and output of the capacitor and detection circuit, and used to prevent the back-up power supply device from discharging electricity to the capacitor and the detection circuit.

2. The circuit for detecting capacitance attenuation of a rectification/filter capacitor according to claim 1, wherein the isolation device includes a plurality of diodes connected in parallel.

3. The circuit for detecting capacitance attenuation of a rectification/filter capacitor according to claim 1, wherein the isolation device includes a plurality of unidirectional thyristors connected in parallel.

4. The circuit for detecting capacitance attenuation of a rectification/filter capacitor according to claim 1, wherein the back-up power supply device is an energy storage element.

5. The circuit for detecting capacitance attenuation of a rectification/filter capacitor according to claim 1, wherein the back-up power supply device is a DC power supply device.

6. A method for detecting capacitance attenuation of a rectification/filter capacitor, comprising steps of
supplying a rectified ripple voltage to a capacitor and a detection circuit, wherein the rectified ripple voltage has a maximum lower than a voltage of a back-up power supply device, whereby the back-up power supply device is isolated from the rectified ripple voltage by an isolation device and takes over to supply power; and
the detection circuit conducting the rectified ripple voltage through a resistor to charge and discharge the capacitor to generate a peak-to-valley ratio and a discharging time, and working out a capacitance of the capacitor through the peak-to-valley ratio, the discharging time and a resistance of the resistor.

7. The method for detecting capacitance attenuation of a rectification/filter capacitor according to claim 6, wherein when an output voltage of the back-up power supply device is lower than the rectified ripple voltage, the isolation device is turned on to let the rectified ripple voltage supply power simultaneously.

8. The method for detecting capacitance attenuation of a rectification/filter capacitor according to claim 6, wherein the rectified ripple voltage is a full-wave rectified voltage.

9. The method for detecting capacitance attenuation of a rectification/filter capacitor according to claim 6, wherein the rectified ripple voltage is a half-wave rectified voltage.
